(19) United States
(12) Patent Application Publication
(10) Pub. No.: US 2024/0348227 A1
(43) Pub. Date: Oct. 17, 2024

(54) PIEZOELECTRIC RESONATOR AND MANUFACTURING METHOD THEREOF

(71) Applicant: AAC Technologies (Nanjing) Co., Ltd., Nanjing (CN)

(72) Inventors: Ke Wu, Nanjing (CN); Shuai Yang, Nanjing (CN); Lirong Zhang, Nanjing (CN); Zhang Zhang, Nanjing (CN); Zhiqiang Zhuang, Nanjing (CN); Chao Wang, Nanjing (CN)

(21) Appl. No.: 18/391,619

(22) Filed: Dec. 20, 2023

Related U.S. Application Data
(63) Continuation of application No. PCT/CN2023/088748, filed on Apr. 17, 2023.

(51) Int. Cl. H03H 9/02; H03H 3/02; H03H 9/17

(52) U.S. Cl. CPC H03H 9/02086; H03H 3/02; H03H 9/173; H03H 9/175; H03H 2003/021; H03H 2003/025

(57) ABSTRACT

The present disclosure provides a piezoelectric resonator, including a bottom electrode, a piezoelectric layer formed on a side of the bottom electrode, a top electrode formed on a side of the piezoelectric layer away from the bottom electrode, an acoustic wave reflection structure formed on a side of bottom electrode away from piezoelectric layer, an insertion layer, and a mass load. The top electrode, piezoelectric layer, bottom electrode, and acoustic wave reflection structure form a resonant region. The insertion layer is formed on a side of top electrode away from piezoelectric layer and/or on the side of bottom electrode away from piezoelectric layer, and at least partially covers the resonant region. The mass load is formed on a side of the insertion layer away from piezoelectric layer, and is at least partially formed in the resonant region. The piezoelectric resonator has high performance, lower process difficulty, higher manufacturability and yield.

### CROSS REFERENCE TO RELATED APPLICATIONS

The present application is a continuation of PCT Patent Application No. PCT/CN2023/088748, filed Apr. 17, 2023, which is incorporated by reference herein in its entirety.

### TECHNICAL FIELD

The present disclosure relates to the field of piezoelectric technology, and in particular to a piezoelectric resonator and a method for manufacturing a piezoelectric resonator.

### BACKGROUND

With the development of communication network technology and electronic information technology, RF front-end chips in communication devices are becoming more and more small and complex. As the most important passive device in RF front-end chips, filters are always broadly researched in recent years. Due to the increasing number of smart devices and the continuous popularity of the Internet of Things and 5G technology, the demand for high-performance filters and multiplexers in the consumer market is increasing. Acoustic resonators are the core units of filters and multiplexers. The current mainstream acoustic resonance technologies include surface acoustic wave (SAW) technology and bulk acoustic wave (BAW) technology. Resonators using SAW technology, due to their simple manufacturing process and low cost, occupy the mainstream market for low and medium frequency (below 2 GHz). The disadvantages of SAW resonators are their low quality factor values, poor material temperature drift, and poor compatibility with semiconductor processes. The filter composed of this resonator has poor rectangular coefficients, high insertion loss, and a large center frequency drift with temperature. What is even more fatal is that as the frequency increases, the spacing between interdigital electrodes of the SAW resonator decreases, which puts higher requirements on the process and deteriorates the reliability of the device. These drawbacks are hindering the application of SAW resonators in higher frequency bands. The emergence of BAW resonators has improved many of the shortcomings of SAW resonators, and mature semiconductor processes have good compatibility with their manufacturing. However, due to the complex process and high manufacturing difficulty of BAW resonators, their costs remain high, making it difficult for them to completely replace SAW resonators in medium-high frequency range, and even lacking competitiveness in the low frequency range. In addition to its development in the field of communication, BAW resonators are also widely used in piezoelectric microphones, pressure sensors, or other sensor fields due to their excellent performance.

BAW resonators differ from SAW resonators in that the BAW resonators use longitudinal waves to generate resonance in piezoelectric thin films, and propagation direction of the longitudinal waves is the thickness direction of piezoelectric material. By adjusting the thicknesses of the piezoelectric material and electrode material, it is convenient to adjust the resonant frequency of the resonator. In order to generate resonance, in addition to the piezoelectric material and electrode layers arranged to sandwiching the piezoelectric material to generate electrical excitation, there are usually acoustic mirrors that allow waves to reflect at interface. Air or Bragg mirrors are the most commonly used mirror structures. A Bragg mirror uses a stacked structure of a plurality of sets of low acoustic impedance materials and a plurality of sets of high acoustic impedance materials, where the plurality of sets of low acoustic impedance materials interleave with the plurality of sets of high acoustic impedance materials, in order to achieve wave reflection. Although this type of mirror has a high reflectivity, it still cannot prevent energy leakage along the mirror. Compared to Bragg mirrors, air has a better reflection effect on waves and blocks the path of energy leakage, so resonators with higher figures of merit can often be manufactured. In order to introduce air as a mirror in the resonant structure, in the related technology, a cavity structure is produced in or on the substrate before depositing the electrode layers and piezoelectric layers. Taking formation of a cavity in the substrate as an example, a sacrificial material is filled in the cavity to make the surface flat, and then the electrode layers and piezoelectric layers are deposited over the cavity and substrate. Finally, a corrosive solution or atmosphere that can corrode the sacrificial material is used to contact with the sacrificial material through a reserved release channel, to release the cavity and form an air mirror structure.

When a BAW resonator is in operation, high-frequency voltage is applied to top electrode and bottom electrode respectively. Under the action of an alternating electric field, the piezoelectric material undergoes deformation, and the suspended film layer over the cavity or acoustic mirror oscillates, producing longitudinal waves parallel to the thickness direction and clutter propagating perpendicular to the thickness direction (along transverse direction). At a specific frequency of alternating voltage, the suspended thin film will undergo resonance, and the device will exhibit special electrical characteristics, thereby achieving the transmission of signals of a specific frequency.

In the related technology, in principle, although the main mode of resonance is longitudinal wave mode, there will still be some parasitic modes formed with excitation of longitudinal waves. These parasitic modes may be standing waves or clutter propagating horizontally. The standing waves form spurious peaks of the electrical characteristic curve of the device, and increase the in-band ripple and insertion loss of the filter. The clutter causes energy leakage, increases insertion loss of the filter, and reduces the quality factor (Q value) of the device.

Based on typical resonator structures, the shortcomings of the related technology are reflected in: 1 the energy in the resonant region is prone to leakage outside the resonant region with accompanying transverse clutter, thereby increasing the insertion loss of the filter and reducing the quality factor (Q value) of the device. 2. During frequency tuning, the thickness of the passivation layer will gradually decrease as the process progresses, which may result in that the passivation layer is not able to fully cover the top electrode layer, especially at the junction where the thickness of the lower layer of the passivation layer changes, therefore the top electrode is exposed and easily corroded in subsequent processes, making the top electrode more prone to failure during use of product. 3. The patterning of mass loads is often achieved by etching, but due to the inability of etching of mass load to completely stop on the top electrode, the top electrode may also be partially etched, resulting in deviations between the actual structure and design. Due to the high correlation between the frequency of the resonator and the thickness of layers, the deviations cause the frequency of the resonator to shift. More seriously, this unexpected etching is uncontrollable in the process and is influenced by the density of pattern, causing inconsistent influences on different elements and ultimately low yield. 4. The addition of mass loads increases change in the thicknesses of the film layers under the passivation layer. With frequency tuning, the passivation layer becomes thinner, making it easier to expose the top electrode layer or mass load, resulting in corrosion and failure of these structures in subsequent processes. 5. The mass loads arranged on the top electrode lead to a decrease in the effective electromechanical coupling coefficient of the resonator, and an increase in clutter near the resonant frequency. Therefore, it is necessary to provide a new resonator to solve the above problems.

### SUMMARY

The present disclosure aims to provide a resonator having at least one insertion layer and at least one mass load, in order to improve performance, reduce process difficulty, and improve manufacturability and yield.

In order to solve the above problems, in the first aspect, the present disclosure provides a piezoelectric resonator, including:
a bottom electrode;
a piezoelectric layer, formed on a side of the bottom electrode;
a top electrode, formed on a side of the piezoelectric layer away from the bottom electrode;
an acoustic wave reflection structure, formed on a side of the bottom electrode away from the piezoelectric layer, where the top electrode, the piezoelectric layer, the bottom electrode, and the acoustic wave reflection structure overlap to form a resonant region;
at least one insertion layer, formed on a side of the top electrode away from the piezoelectric layer and/or on the side of the bottom electrode away from the piezoelectric layer, where the at least one insertion layer at least partially covers the resonant region; and
at least one mass load, where each mass load of the at least one mass load is formed on a side of a respective insertion layer of the at least one insertion layer away from the piezoelectric layer, the at least one mass load is at least partially formed in the resonant region.

As an improvement, the piezoelectric resonator further includes a substrate formed on the side of the bottom electrode away from the piezoelectric layer.

As an improvement, the acoustic wave reflection structure is formed by a recess on a surface of the substrate facing towards the bottom electrode or by a cavity formed between the substrate and the bottom electrode, where the cavity is at least partially formed in the resonant region.

As an improvement, the acoustic wave reflection structure is a Bragg mirror formed on a side of the bottom electrode away from the top electrode and formed at least partially in the resonant region.

As an improvement, a distance between an outer edge of the at least one mass load and a respective outer edge of the resonant region is less than or equal to 8 μm.

As an improvement, the insertion layer includes one or more of SiN, AlN, Al₂O₃, SiO₂, and polycrystalline silicon.

As an improvement, a thickness of each insertion layer of the at least one insertion layer ranges from 1 nm to 1000 nm.

As an improvement, the at least one mass load forms a structure of closed annulus.

As an improvement, the at least one mass load forms a structure of unclosed annulus obtained by removing at least one corner or side of a structure of closed annulus.

As an improvement, the at least one mass load forms a structure of unclosed annulus obtained by forming at least one notch on a structure of closed annulus, where the at least one notch has side walls opposite to each other, and the at least one notch is perpendicular to outer edges of the structure of unclosed annulus along an extension direction of the side walls.

As an improvement, the structure of unclosed annulus has two or more than two notches, and the two notches or at least two notches of the more than two notches are formed on a same longitudinal section of the piezoelectric resonator.

As an improvement, a width of each notch is less than one-fifth of a length of a respective side of the resonant region or is less than 10 μm.

As an improvement, the at least one mass load is formed at a center of the resonant region.

As an improvement, the at least one mass load is arranged to form a shape same as a shape of the resonant region, and each outer edge of outer edges of the shape formed by the at least one mass load is parallel to a respective outer edge of outer edges of the resonant region.

As an improvement, at least one outer edge of outer edges of a shape formed by the at least one mass load is not parallel to at least one respective outer edge of outer edges of the resonant region.

As an improvement, insertion layers and mass loads are formed on either sides of the piezoelectric layer. The insertion layers include a first insertion layer and a second insertion layer, the first insertion layer is formed on the side of the top electrode away from the piezoelectric layer, and the second insertion layer is formed on the side of the bottom electrode away from the piezoelectric layer;

the mass loads include a first mass load and a second mass load, the first mass load is formed on a side of the first insertion layer away from the top electrode, and the second mass load is formed on a side of the second insertion layer away from the bottom electrode.

As an improvement, the piezoelectric resonator further includes at least one passivation layer, where each passivation layer of the at least one passivation layer is formed on the side of a respective insertion layer of the at least one insertion layer away from the piezoelectric layer, and the at least one passivation layer at least partially covers the resonant region.

In the second aspect, the present disclosure provides a method for manufacturing a piezoelectric resonator, including:
forming a bottom electrode layer on a substrate by deposition, and patterning the bottom electrode layer to obtain a bottom electrode, where the substrate has an acoustic wave reflection structure or a sacrificial layer structure formed on a surface of the substrate;
forming a piezoelectric layer by deposition on a side of the bottom electrode layer away from the substrate;
forming a top electrode layer by deposition on a side of the piezoelectric layer away from the bottom electrode layer;
forming an insertion layer by deposition on a side of the top electrode layer away from the piezoelectric layer; and
forming a mass load layer by deposition on a side of the insertion layer away from the top electrode layer, and patterning the mass load layer to obtain at least one mass load.

As an improvement, forming the top electrode layer by deposition on the side of the piezoelectric layer away from the bottom electrode layer, includes: patterning the top electrode layer to obtain a top electrode.

As an improvement, after patterning the mass load layer, the method further includes:
forming a passivation layer by deposition on a side of the mass load layer away from the insertion layer.

As an improvement, the method further includes:
pattering the passivation layer, the mass load layer, the insertion layer, and the top electrode layer, to make an edge of the passivation layer, an edge of the mass load layer, an edge of the insertion layer, and an edge of the top electrode layer align with each other.

As an improvement, the method further includes: forming a cavity by etching on a surface of the substrate; depositing a sacrificial material to fill the cavity; and polishing the sacrificial material by chemical mechanical polishing to make the sacrificial material flush with the surface of the substrate; where the sacrificial layer structure is configured to be released at an end of the method to empty the cavity, and the cavity is configured to reflect acoustic waves to form the acoustic wave reflection structure.

As an improvement, the method further includes: forming a sacrificial layer by deposition on the substrate; patterning the sacrificial layer; and forming a support layer by deposition on a side of the sacrificial layer away from the substrate; where the sacrificial layer is configured to be released at an end of the method to form a cavity, and the cavity is configured to reflect acoustic waves to form the acoustic wave reflection structure.

As an improvement, the method further includes: forming a support layer by deposition on the substrate; forming a cavity on a surface of the support layer away from the substrate by etching the support layer; depositing a sacrificial material to fill the cavity; and leveling the sacrificial material by chemical mechanical polishing to make the sacrificial material flush with the surface of the substrate; where the sacrificial layer is configured to be released at an end of the method to empty the cavity, and the cavity is configured to reflect acoustic waves to form the acoustic wave reflection structure.

As an improvement, the method further includes: forming a plurality of layers of materials having different acoustic impedances on the substrate by deposition to form a Bragg mirror configured to reflect acoustic waves and to form the acoustic wave reflection structure.

As an improvement, the method further includes: etching the passivation layer on a surface of the passivation layer away from the mass load layer to form a top electrode contacting hole communicating with the top electrode layer.

As an improvement, the method further includes: etching the passivation layer and/or the piezoelectric layer on a surface of the passivation layer away from the mass load layer to form a bottom electrode contacting hole communicating with the bottom electrode.

As an improvement, the method further includes: forming an interconnecting metal layer by deposition on a side of the passivation layer away from the mass load layer, wherein the interconnecting metal layer fills the top electrode contacting hole and/or the bottom electrode contacting hole.

Compared with the related technologies, in the piezoelectric resonator provided by the present disclosure, the piezoelectric layer is formed on a side of the bottom electrode; the top electrode is formed on a side of the piezoelectric layer away from the bottom electrode; the acoustic wave reflection structure is formed on a side of the bottom electrode away from the piezoelectric layer, and the top electrode, the piezoelectric layer, the bottom electrode, and the acoustic wave reflection structure overlap to form a resonant region; the at least one insertion layer is formed on a side of the top electrode away from the piezoelectric layer and/or on the side of the bottom electrode away from the piezoelectric layer, and the at least one insertion layer at least partially covers the resonant region; each mass load of the at least one mass load is formed on a side of a respective insertion layer of the at least one insertion layer away from the piezoelectric layer, and the at least one mass load is at least partially formed in the resonant region. By using the at least one insertion layer as etching-stop layer(s), during patterning of the at least one mass load, it can be ensured that the etching of the at least one mass load stops at the at least one insertion layer and the top electrode will not be etched, thereby improving the consistency of devices in the process and improving the yield of process. By introducing the at least one insertion layer on the top electrode, lower structures can be protected, not only preventing these structures from being damaged during processing, but also protecting these structures from corrosion by such as water vapor in the environment during use of the device, thereby improving the reliability of the device. The present disclosure also defines the positions of outer edges of the at least one mass load, thereby ensuring that the at least one mass load can substantially improve the performance of the resonator and increase the figure of merit (FOM) for comprehensive performance of the resonator.

### BRIEF DESCRIPTION OF DRAWINGS

In order to illustrate the technical solutions in the embodiments of the present disclosure more clearly, the drawings to be used in the description of the embodiments will be briefly described below. It is obvious that the drawings mentioned in the following description are only some embodiments of the present disclosure. For those of ordinary skill in the art, other drawings may also be obtained in accordance with these drawings without any inventive effort.

FIG. 1 is a structural schematic diagram of the piezoelectric resonator according to some embodiments of the present disclosure.

FIG. 2 is a schematic diagram of the at least one mass load and the resonant region of the piezoelectric resonator according to some embodiments of the present disclosure.

FIG. 3 is a schematic diagram of a leading-out region for top electrode and the resonant region of the piezoelectric resonator according to some embodiments of the present disclosure.

FIG. 4 is a curve graph of relationship between the standardized overall figure of merit (FOM) for the resonator and positions of outer edges of the at least one mass load of the piezoelectric resonator according to some embodiments of the present disclosure.

FIG. 5 is another schematic diagram of the at least one mass load and the resonant region of the piezoelectric resonator according to some embodiments of the present disclosure.

FIG. 6 is still another schematic diagram of the at least one mass load and the resonant region of the piezoelectric resonator according to some embodiments of the present disclosure.

FIG. 7 is yet another schematic diagram of the at least one mass load and the resonant region of the piezoelectric resonator according to some embodiments of the present disclosure.

FIG. 8 is one more schematic diagram of the at least one mass load and the resonant region of the piezoelectric resonator according to some embodiments of the present disclosure.

FIG. 9 is another structural schematic diagram of the piezoelectric resonator according to some embodiments of the present disclosure.

FIG. 10 is a schematic diagram of the at least one mass load and the resonant region of the piezoelectric resonator shown in FIG. 9.

FIG. 11 is still another structural schematic diagram of the piezoelectric resonator according to some embodiments of the present disclosure.

FIG. 12 is yet another structural schematic diagram of the piezoelectric resonator according to some embodiments of the present disclosure.

FIG. 13 is a flowchart of a method for manufacturing a piezoelectric resonator according to some embodiments of the present disclosure.

### DETAILED DESCRIPTION OF EMBODIMENTS

The following will provide a clear and complete description of the technical solutions in the embodiments of the present disclosure, in conjunction with the accompanying drawings in the embodiments of the present disclosure. The specific embodiments/implements recited herein are specific embodiments of the present disclosure, which are used to illustrate the concept of the present disclosure and are explanatory and exemplary, and shall not be interpreted as limiting the embodiments of the present disclosure or the scope of the present disclosure. In addition to the embodiments recited herein, those skilled in the art may also adopt other obvious technical solutions based on the content disclosed in the claims and description of the present disclosure. These technical solutions, including adopting any obvious substitution and modification of the embodiments recited herein, are within the scope of protection of the present disclosure.

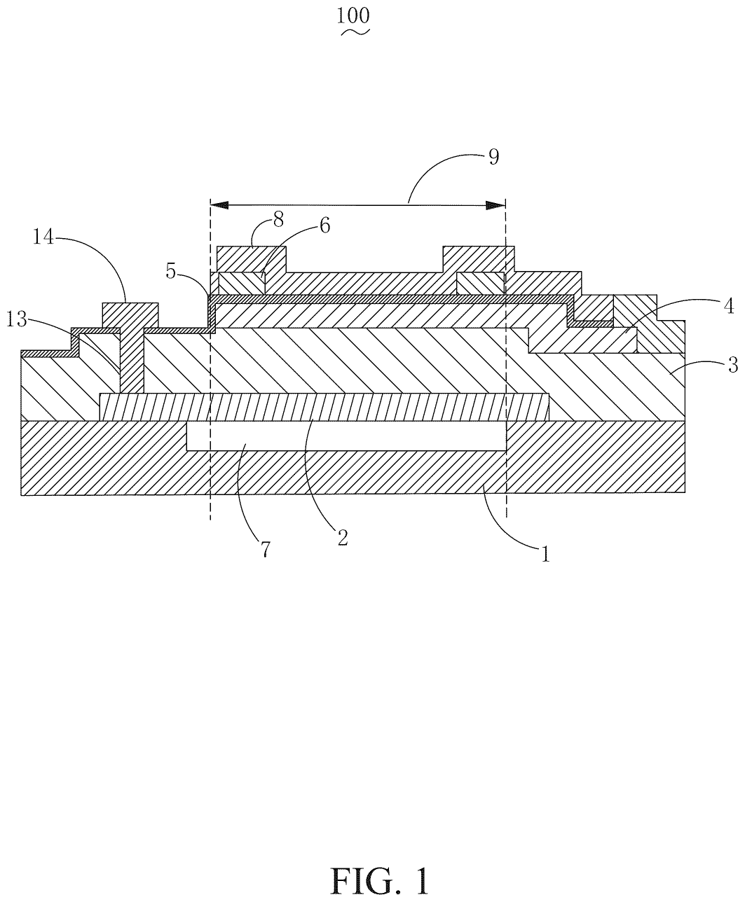

The following will provide a specific description of the present disclosure in conjunction with FIGS. 1 to 12. The present disclosure provides a piezoelectric resonator 100 including a substrate 1, a bottom electrode 2, a piezoelectric layer 3, a top electrode 4, an acoustic wave reflection structure 7, at least one insertion layer 5, and at least one mass load 6.

The substrate 1 is formed on the side of the bottom electrode away from the piezoelectric layer. The bottom electrode 2 is formed on a side of the substrate 1.

The piezoelectric layer 3 is formed on a side of the bottom electrode 2 away from the substrate 1.

The top electrode 4 is formed on a side of the piezoelectric layer 3 away from the bottom electrode 2.

The acoustic wave reflection structure 7 is formed on a side of the bottom electrode 2 away from the piezoelectric layer 3, and the top electrode 4, the piezoelectric layer 3, the bottom electrode 2, and the acoustic wave reflection structure 7 overlap to form a resonant region 9.

The at least one insertion layer 5 is formed on a side of the top electrode 4 away from the piezoelectric layer 3 and/or on the side of the bottom electrode 2 away from the piezoelectric layer 3. The at least one insertion layer 5 at least partially covers the resonant region 9. There must be at least one mass load 6 arranged in the resonant region 9, and there may be or not be mass load outside the resonant region 9, which would not be limited in detail here.

Each mass load of the at least one mass load 6 is formed on a side of a respective insertion layer of the at least one insertion layer 5 away from the piezoelectric layer 3, and the at least one mass load 6 is at least partially formed in the resonant region 9. The at least one mass load 6 is configured to adjust the acoustic impedance and frequency of the piezoelectric resonator 100. The at least one insertion layer 5 and the at least one mass load 6 are concurrently formed on one side or either sides of the piezoelectric layer 3. By using the at least one insertion layer 5 as etching-stop layer(s), during patterning of the at least one mass load 6, it can be ensured that the etching of the at least one mass load 6 stops at the at least one insertion layer 5 and the top electrode 4 will not be etched. Thus, the at least one insertion layer 5 can improve the consistency of devices in the process and can improve the yield of process. By introducing the at least one insertion layer 5 on the top electrode 4, lower structures can be protected, not only preventing these structures from being damaged during processing, but also protecting these structures from corrosion by such as water vapor in the environment during use of the device, thereby improving the reliability of the device.

The at least one insertion layer 5 is generally made of protective materials, such as one of materials of SiN, AlN, Al₂O₃, SiO₂, and polycrystalline silicon that can provide protection or a combination thereof. According to the process capability and requirements, a thickness of each insertion layer of the at least one insertion layer may range from 1 nm to 1000 nm. In order to maintain the good protective effect of the etching-stop layer(s), while considering the thicknesses of the electrode layers and the piezoelectric layer, as well as the overall frequency of the device, the preferred range for the thickness of each insertion layer of the insertion layer is 30 nm to 500 nm. It should be pointed out that the thicknesses of the electrode layers and the piezoelectric layer generally vary with the frequency in the designs of resonators and filters of different frequencies. The lower the working frequency of the device, the thicker the overall thickness, the lower the sensitivity of the device performance to the thickness of the at least one insertion layer, and the wider the selection range of the at least one insertion layers is. The higher the working frequency of the device, the thinner the overall thickness, and the higher the sensitivity of the device performance to the thickness of the at least one insertion layer, thus a relative small thickness is generally selected for the at least one insertion layer, and the selection range is narrower. The present disclosure further limits the positions of the outer edges of the at least one mass load 6, ensuring that the at least one mass load can substantially improve the performance of the resonator, thereby improving FOM.

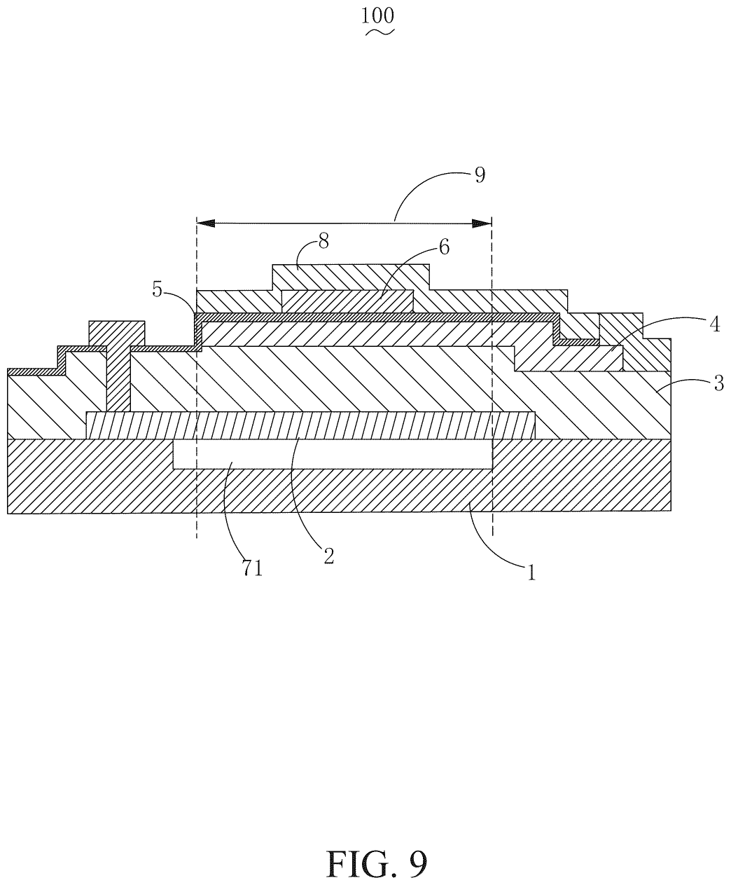

In the piezoelectric resonator 100 provided by the present disclosure, referring to FIGS. 1 and 9, the acoustic wave reflection structure 7 is formed by a recess on a surface of the substrate 1 facing towards the bottom electrode 2 or by a cavity 71 formed between the substrate 1 and the bottom electrode 2, and the cavity 71 is at least partially formed in the resonant region 9.

The cavity 71 is formed by etching the substrate 1 and filling and releasing a sacrificial layer, or by forming and releasing the sacrificial layer on the substrate 1, or by using SOI wafer and related cavity processes, or by forming the sacrificial layer on a stack, bonding another wafer, and then releasing the sacrificial layer.

It should be understood that in some other embodiments, the acoustic wave reflection structure 7 may be a Bragg mirror (not shown) formed on a side of the bottom electrode 2 away from the top electrode 4 and formed at least partially in the resonant region 9. Selective design may be carried out according to actual requirements. The following will provide further description of the present disclosure in conjunction with specific embodiments.

As shown in FIG. 1, the insertion layer 5 is formed on a side of the top electrode 4 away from the piezoelectric layer 3, and a distance between an outer edge of the at least one mass load 6 and a respective outer edge of the resonant region 9 is less than or equal to 8 μm. The outer edge of the at least one mass load 6 may be arranged on an outer side of the respective outer edge of the resonant region 9, or may coincide with the respective outer edge of the resonant region 9, or may be arranged on an inner side of the respective outer edge of the resonant region 9. However, in order for the at least one mass load to substantially improve the performance of the resonator and to improve the FOM, the distance between the outer edge of the at least one mass load and the respective outer edge of the resonant region 9 shall not exceed 8 μm.

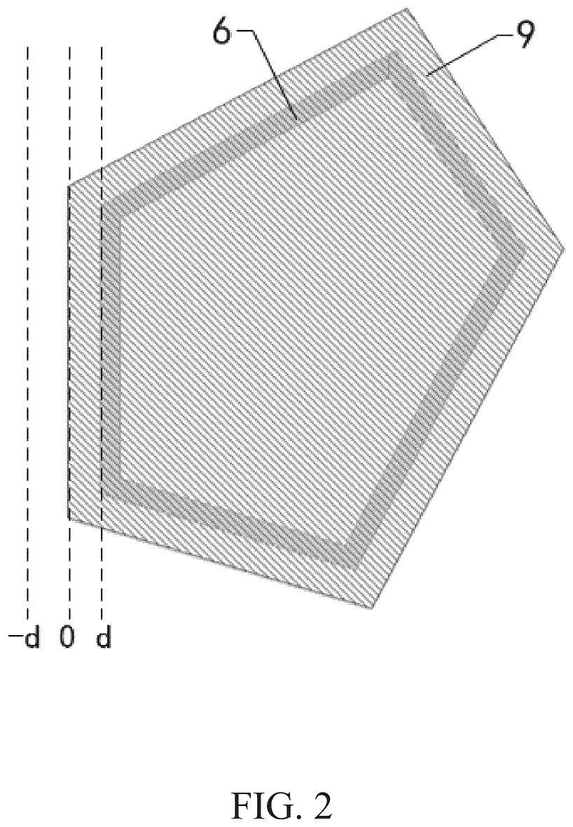

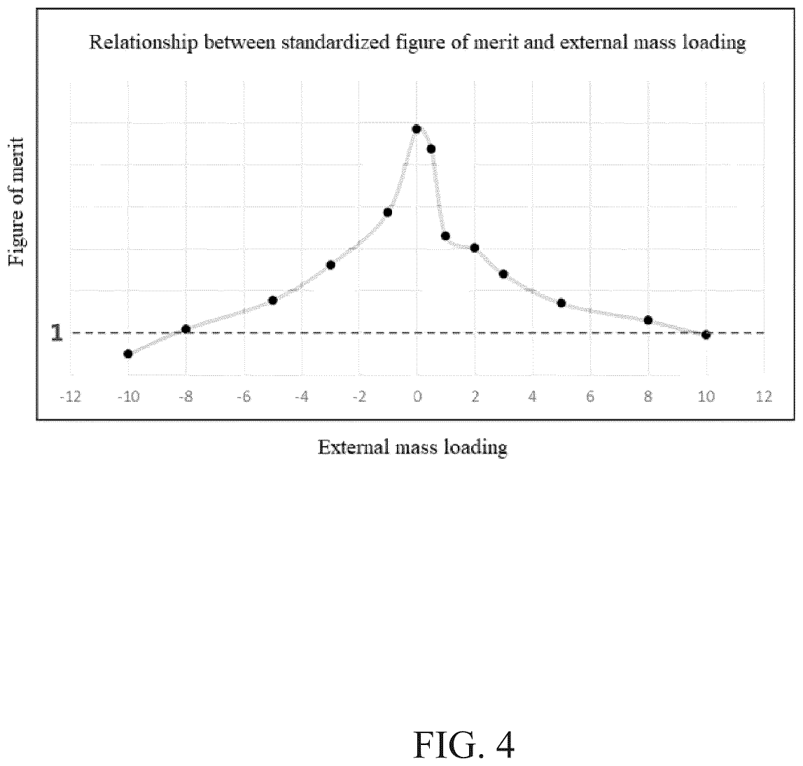

As shown in FIG. 2, the outer edge of the at least one mass load 6 may be arranged on the inner side of the respective outer edge of the resonant region 9 (d>0), or may coincide with the respective outer edge of the resonant region 9 (d=0), or may be arranged on an outer side of the respective outer edge of the resonant region 9 (d<0). FIG. 4 shows the variation curve of measured FOM (Q*kts) of the piezoelectric resonator 100 with d, where the FOM represents the figure of merit for comprehensive performance of the resonator, which is a comprehensive indicator for evaluating the performance of the resonator. In the drawing, values of FOM have been normalized, and only when FOM>1, the at least one mass load 6 can improve the performance of the piezoelectric resonator 100.

It can be seen in FIG. 4 that when the outer edge of the at least one mass load 6 coincides with the respective outer edge of the resonant region 9 (d=0), the performance of the piezoelectric resonator 100 has the greatest improvement; when the distance between the outer edge of the at least one mass load 6 and the respective outer edge of the resonant region 9 meets−1 μm<d<1 μm, the performance of the piezoelectric resonator 100 has a relative great improvement; and when the distance between the outer edge of the at least one mass load 6 and the respective outer edge of the resonant region 9 meets −8 μm<d<8 μm, the at least one mass load 6 provides an improvement to the performance of the piezoelectric resonator 100. According to the measured results, the structure of the piezoelectric resonator 100 according to the present disclosure limits that the distance between the outer edge of the at least one mass load 6 and the respective outer edge of the resonant region 9 does not exceed 8 μm. When the distance is less than 1 μm, the performance has a greater improvement, and when the outer edge of the at least one mass load 6 coincides with the respective outer edge of the resonant region 9 (d=0), the performance has the greatest improvement.

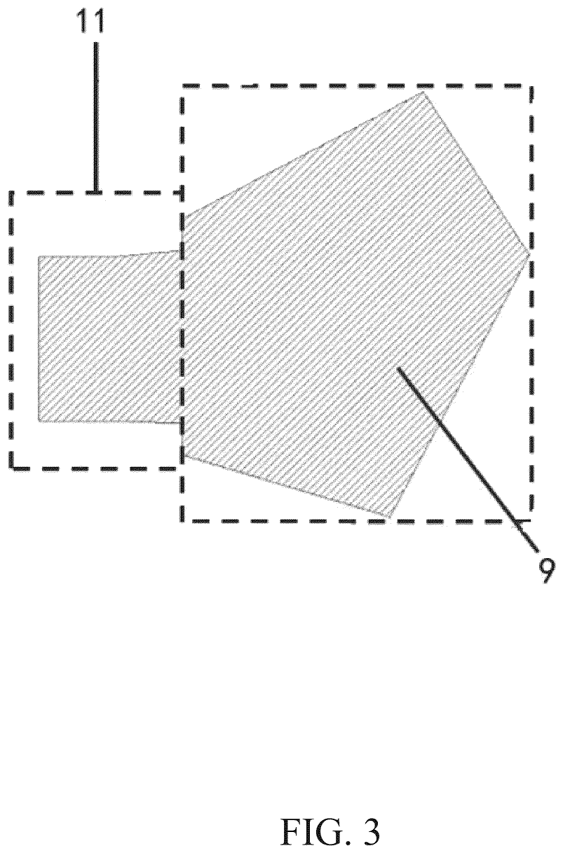

It should be noted that, the present disclosure defines a relationship between the outer edge of the at least one mass load 6 and the respective outer edge of the resonant region 9, but the outer edges of the resonant region 9 shall not be replaced with outer edges of an electrode region. As shown in FIG. 3, the region for the top electrode 4 includes the resonant region 9 and a leading-out region 11 for top electrode. Thus, an area determined by the outer edges of the resonant region 9 distinguishes from that determined by outer edges of the electrode region (9+11) and are not equivalent. When it is defined that a distance between the outer edge of the at least one mass load 6 and a respective outer edge of the electrode region does not exceed 8 μm, the additional mass load(s) 6, due to the change in the defined area, arranged in the leading-out region 11 for top electrode and peripheral region thereof may obstruct the electrical connection of the top electrode 4, causing an open circuit in the piezoelectric resonator 100. In order to overcome the obstruction of the additional mass load(s) 6, an additional operation of etching the additional mass load(s) 6 is required in the process, which actually increases the difficulty of the process.

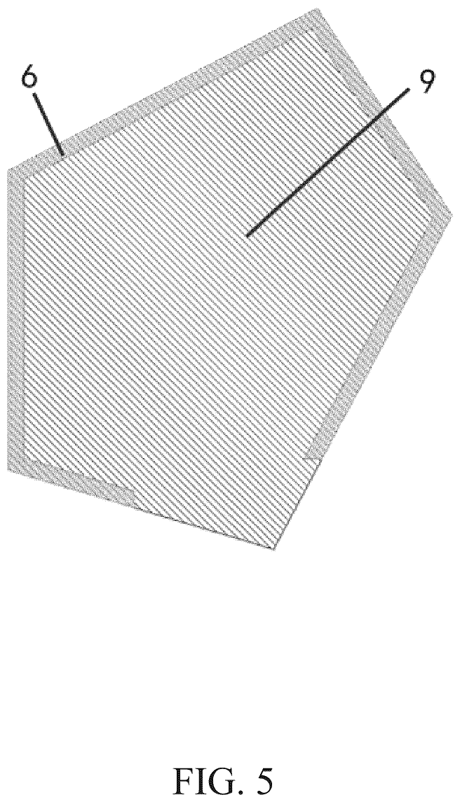

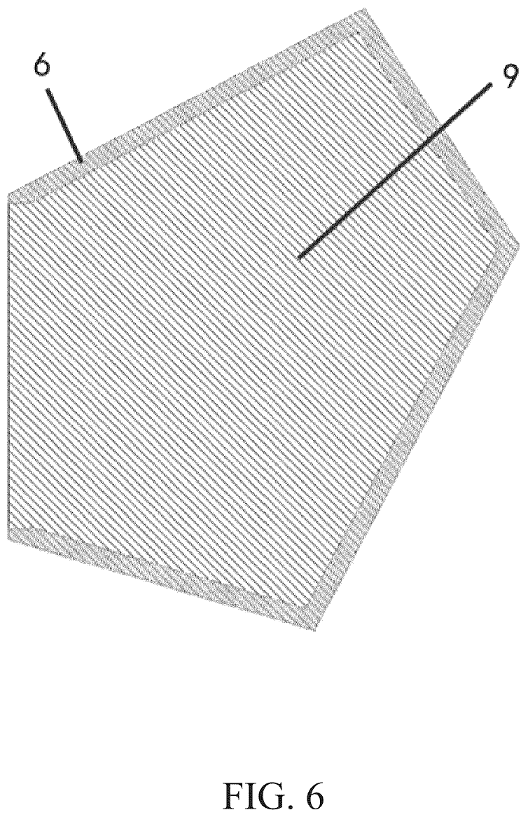

As shown in FIGS. 5 and 6, the at least one mass load 6 is arranged on the periphery of the resonant region 9 to form a structure of closed annulus or a structure of unclosed annulus, and the at least one mass load 6 at least covers a part of the resonant region 9.

The at least one mass load may form a structure of unclosed annulus, as shown in FIGS. 5 and 6, the structure of unclosed annulus is obtained by removing at least one corner or side of the structure of closed annulus. On the premise of having little impact on the Q value, removing part of the at least one mass load 6 can promote the mutual conversion of mechanical energy and electrical energy, and increase the effective electromechanical coupling coefficient. When a plurality of piezoelectric resonators 100 are cascaded into a filter, bandwidth of the filter can be effectively expanded. The region(s) in which part of the at least one mass load 6 is removed does not lead to acoustic impedance mismatch, although partial energy leakage may be caused due to transverse waves that cannot propagate to this region by reflection, the clutter near the resonant point of the piezoelectric resonator 100 is weakened, which improves the overall performance of the filter. Removing part of the at least one mass load 6 is more adaptive to the metal-lift-off process, thereby increasing success rate of patterning and process yield.

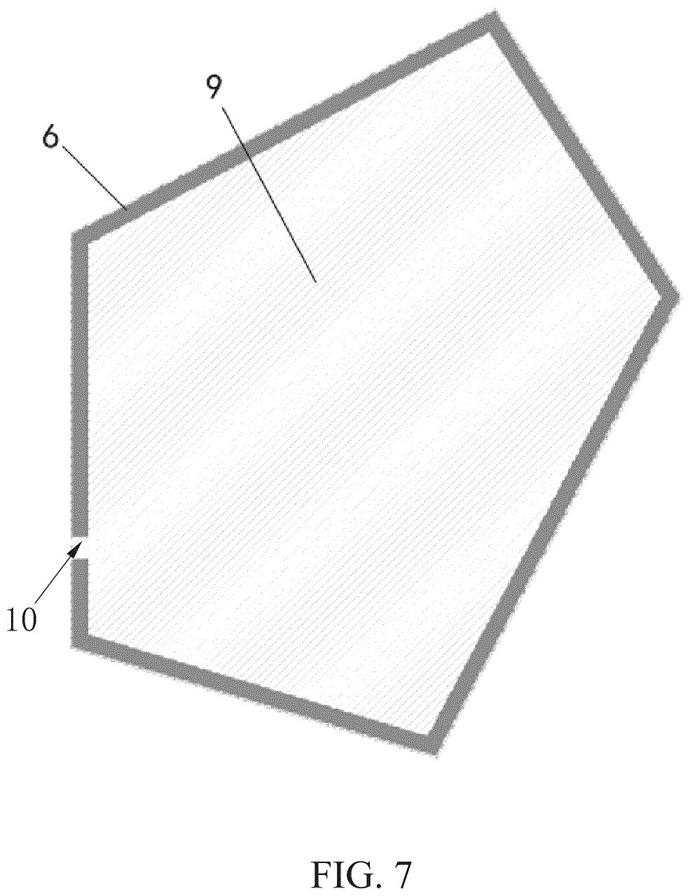

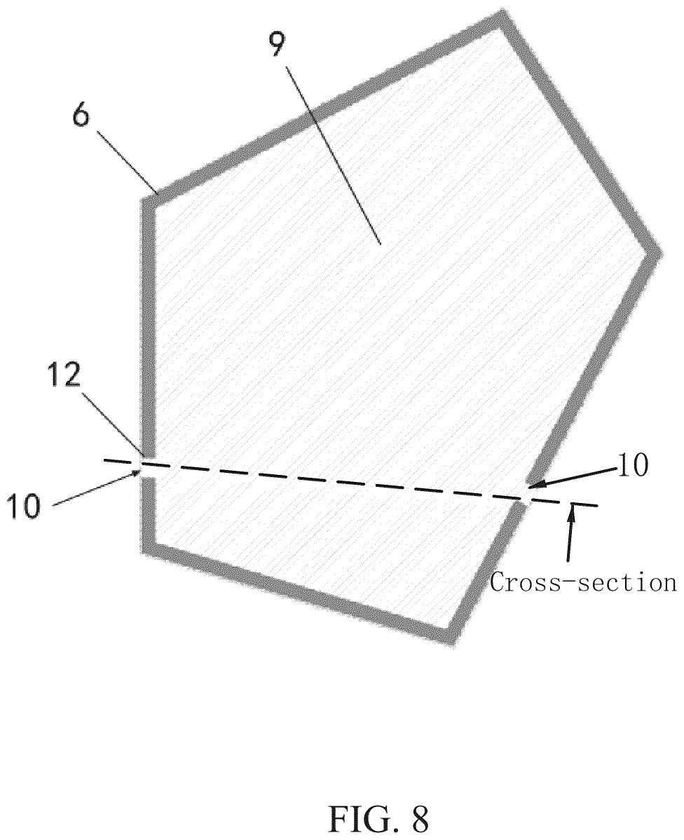

As shown in FIGS. 7 and 8, the structure of unclosed annulus also may be obtained by forming at least one notch 10 on the structure of closed annulus. A width of each notch 10 is less than one-fifth of a length of a respective side of the resonant region 9 or is less than 10 μm.

As shown in FIG. 7, the at least one notch 10 has side walls 12 opposite to each other, and the at least one notch 10 is perpendicular to outer edges of the structure of unclosed annulus along an extension direction of the side walls. An extension direction of the at least one notch 10 perpendicular to the outer edges of the structure of unclosed annulus helps to release concentrated energy of acoustic waves, thereby preventing excessive energy of standing waves and from generating relatively strong clutter. But the size of the at least one notch 10 should not be too large, otherwise the at least one notch will lead to more energy leakage and cause a significant decrease in Q value. Considering the proportion of the width of each notch 10, process windows, and the wavelengths of standing waves, it is preferred for the at least one notch 10 to be less than one-fifth of a length of a respective side of the resonant region 9 or is less than 10 μm.

In some other embodiments, as shown in FIG. 8, the structure of unclosed annulus is obtained by forming at least two notches 10 on the structure of closed annulus, and at least two notches 10 of a plurality of notches 10 are formed on a same section of the piezoelectric resonator. By forming the plurality of notches 10 and forming at least two notches 10 on a same section of the piezoelectric resonator 100, compared with forming a single notch, concentrated energy of acoustic waves can be released more effectively, thereby preventing excessive energy of standing waves and from generating relatively strong clutter.

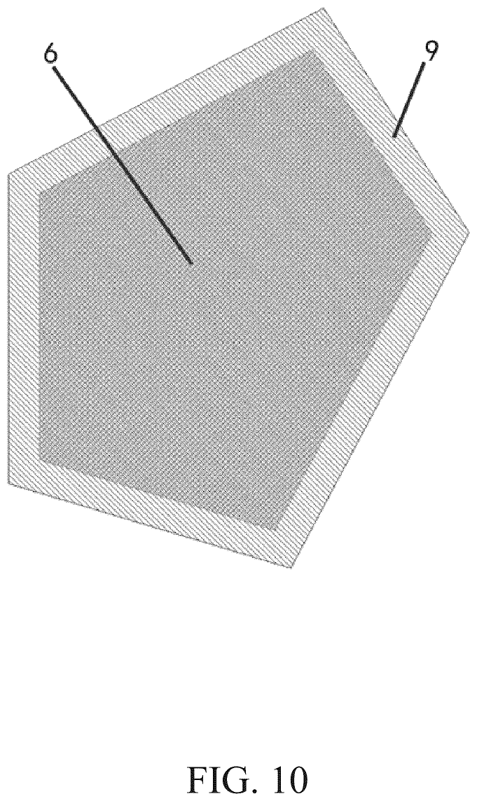

As shown in FIGS. 9 and 10, the insertion layer 5 is formed on a side of the top electrode 4 away from the piezoelectric layer 3, the at least one mass load 6 is formed at a center of the resonant region 9, and the periphery of the at least one mass load 6 is arranged on the inner side of the periphery of the resonant region 9. By not arranging the at least one mass load 6 on the outer side of the resonant region 9, the energy of acoustic waves is more easily leaked outside the resonant region 9, thereby reducing the energy of standing waves and weakening the clutter near the resonant point of the piezoelectric resonator 100. Due to the coverage of the at least one mass load 6 in most region, the frequency of piezoelectric resonator 100 can be adjusted, and cascaded piezoelectric resonators 100 with different frequencies can be used for filter design with large bandwidth or special purposes.

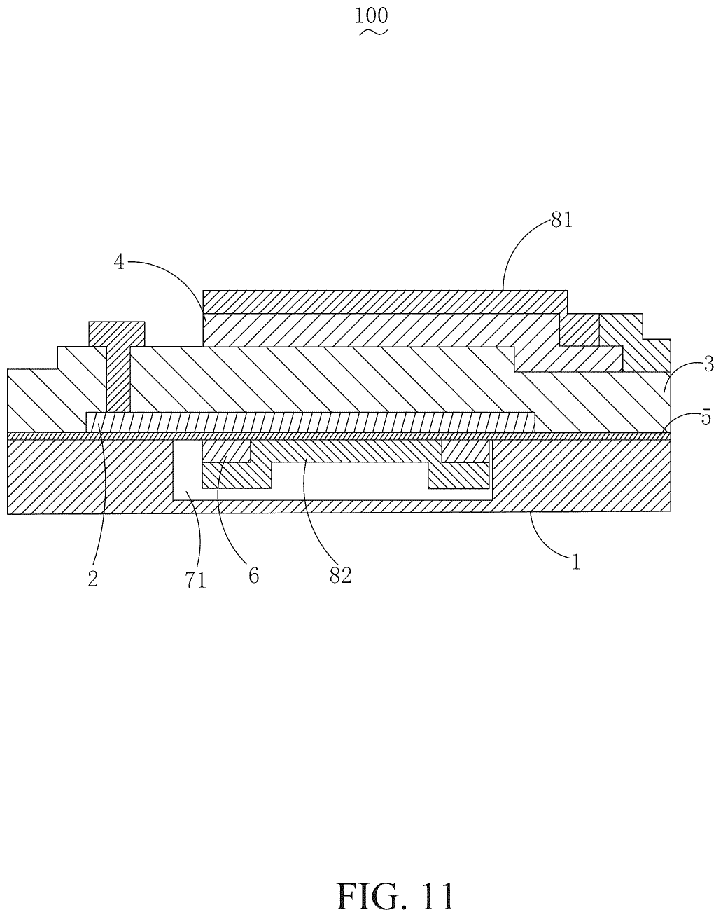

As shown in FIG. 11, the insertion layer 5 is formed on the side of the bottom electrode 2 away from the piezoelectric layer 3, the at least one mass load 6 is formed on a side of the insertion layer 5 away from the bottom electrode 2, and the at least one mass load 6 is arranged in the cavity 71. By forming the insertion layer 5 and the at least one mass load 6 on a side of the bottom electrode 2, similar to the structure of forming the insertion layer and the at least one mass load on a side of the top electrode 4, the performance of the piezoelectric resonator 100 can be improved. Moreover, by forming the insertion layer 5 and the at least one mass load 6 on a side of the bottom electrode 2, more flexibility to the design of the top electrode 4 can be obtained. For example, forming an additional piezoelectric layer 3 on the top electrode 4 requires a simple and as flat as possible top structure of the top electrode 4, so it is not suitable to arrange the at least one mass load 6 structure. In this case, forming the at least one mass load 6 on a side of the bottom electrode 2 can ensure the high performance of the piezoelectric resonator 100 and obtain a flat top electrode 4.

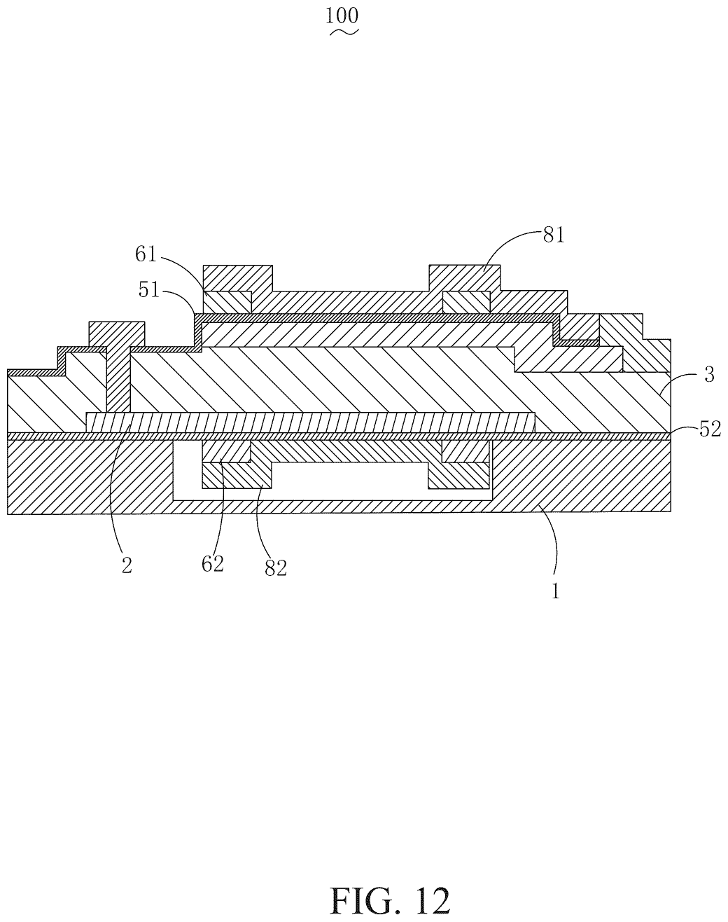

As shown in FIG. 12, insertion layers 5 and mass loads 6 are formed on either sides of the piezoelectric layer 3. The insertion layers 5 include a first insertion layer 51 and a second insertion layer 52, the first insertion layer 51 is formed on the side of the top electrode 4 away from the piezoelectric layer 3, and the second insertion layer 52 is formed on the side of the bottom electrode 2 away from the piezoelectric layer 3. The mass loads 6 include a first mass load 61 and a second mass load 62, the first mass load 61 is formed on a side of the first insertion layer 51 away from the top electrode 4, and the second mass load 62 is formed on a side of the second insertion layer 52 away from the bottom electrode 2. The insertion layers 5 and the mass loads 6 are formed on the top electrode 4 and the bottom electrode 2, respectively, according to the requirements of the piezoelectric resonator 100, the relevant size parameters of the first and second mass loads 6 may be the same to achieve constraints on acoustic waves of some specific frequencies. Compared with a single insertion layer 5 cooperating with the at least one mass load 6, energy leakage can be limited more efficiently. The relevant size parameters of the first and second mass loads 6 may also be different, to respectively constraint acoustic waves of different frequencies, which can also reduce energy leakage. By forming the insertion layers 5 and the mass loads 6 on the top electrode 4 and the bottom electrode 2, respectively, the design parameters of the piezoelectric resonator 100 can be increased, and an optimal choice can be made between the performance of the piezoelectric resonator 100 and the parasitic resonance effect introduced by the mass loads 6 by adjusting the relevant size parameters of the first and second mass loads 6. Compared with a single insertion layer 5 cooperating with the at least one mass load 6, at least the same performance, weaker parasitic resonance or the same parasitic resonance, and better performance can be achieved.

In some embodiments, the material and structural dimensions of the first insertion layer 51 may be the same as or different from those of the second insertion layer 52. The material and structural dimensions of the first mass load 61 may be the same as or different from those of the second mass load 62. The material and structural dimensions of the bottom electrode 2 may be the same as or different from those of the top electrode 4.

Referring to FIGS. 1 and 11 to 12, the piezoelectric resonator 100 provided by the present disclosure further includes at least one passivation layer 8, a respective passivation layer of the at least one passivation layer 8 is formed on a side of the top electrode 4 and a respective insertion layer of the at least one insertion layer 5 away from the top electrode 4 and/or formed on a side of the bottom electrode 2 and a respective insertion layer of the at least one insertion layer 5 away from the bottom electrode 2, and the at least one passivation layer 8 at least partially covers the resonant region 9. The at least one passivation layer 8 is used to protect the top electrode 4 and/or bottom electrode 2, prevent corrosion of the top electrode 4 and bottom electrode 2, and improve the service life of the piezoelectric resonator 100. Moreover, the at least one passivation layer is often used for fine tuning of and compensation for the frequencies of the resonator.

In some embodiments, as shown in FIGS. 11 and 12, the at least one passivation layer 8 includes a first passivation layer 81 formed on a side of the first mass load 61 away from the top electrode 4 and a second passivation layer 82 formed on a side of the second mass load 62 away from the bottom electrode 2. The first passivation layer 81 and the second passivation layer 82 are used to protect the first mass load 61 and the second mass load 62.

A surface of the passivation layer 8 away from the at least one mass load 6 is etched to etch the passivation layer and/or the piezoelectric layer 3, thereby forming a bottom electrode contacting hole 13 communicating with the bottom electrode 2. A conductive column 14 is inserted into the bottom electrode contacting hole 13 to achieve electrical connection between the bottom electrode 2 and the top electrode 4.

In the embodiments as shown in FIGS. 1 to 12, each outer edge of outer edges of the shape formed by the at least one mass load 6 is parallel to a respective outer edge of outer edges of the resonant region 9. It can be understood that in some other embodiments, each outer edge of the shape formed by the at least one mass load 6 may be not parallel to a respective outer edge of the resonant region 9. Moreover, in some other embodiments, the outer edges of the at least one mass load 6 may be not shaped as straight lines, but may be shaped as arcs or polygonal lines. Therefore, the edges of the at least one mass load may be designed according to actual design requirements, which is still within the scope of protection of the present disclosure.

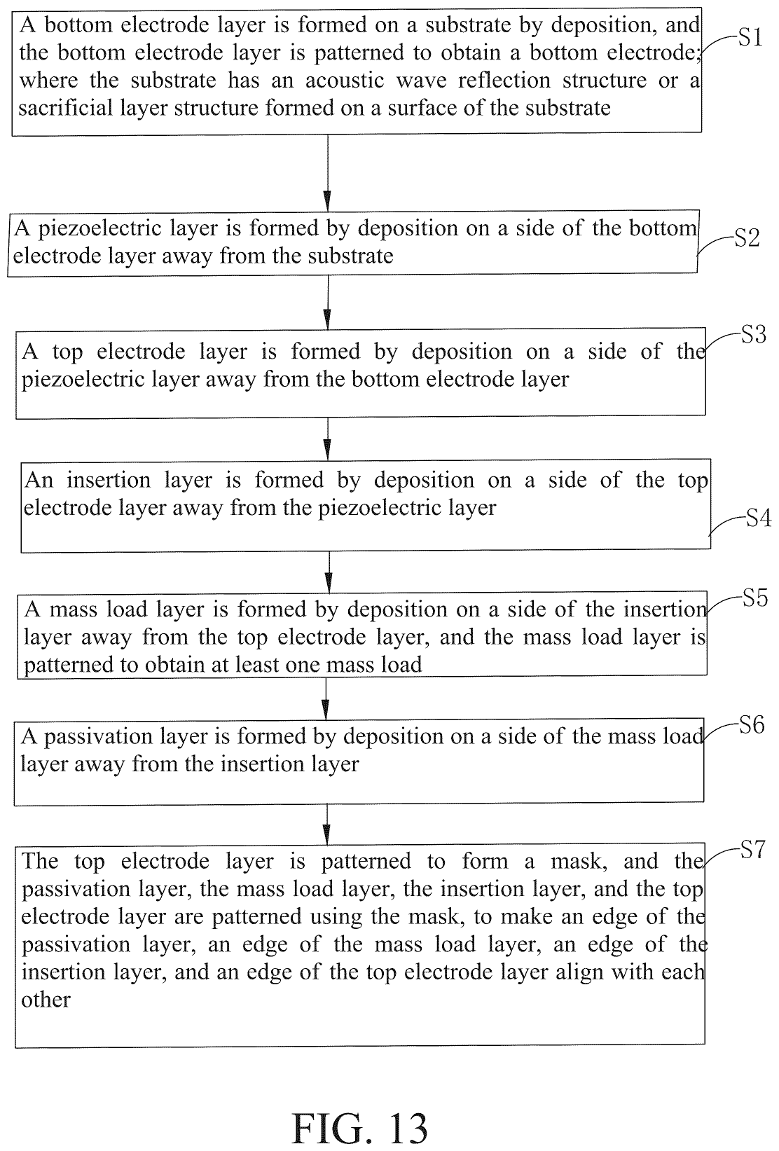

Referring to FIG. 13, the present disclosure further provides a method for manufacturing a piezoelectric resonator, including:
at S1, a bottom electrode layer is formed on a substrate by deposition, and the bottom electrode layer is patterned to obtain a bottom electrode; where the substrate has an acoustic wave reflection structure or a sacrificial layer structure formed on a surface of the substrate;
at S2, a piezoelectric layer is formed by deposition on a side of the bottom electrode layer away from the substrate;
at S3, a top electrode layer is formed by deposition on a side of the piezoelectric layer away from the bottom electrode layer;
at S4, an insertion layer is formed by deposition on a side of the top electrode layer away from the piezoelectric layer; and
at S5, a mass load layer is formed by deposition on a side of the insertion layer away from the top electrode layer, and the mass load layer is patterned to obtain at least one mass load.

In the piezoelectric resonator obtained by performing the above operations S1 to S5, by using the insertion layer as etching-stop layer(s), during patterning of the at least one mass load, it can be ensured that the etching of the at least one mass load stops at the insertion layer and the top electrode will not be etched. The insertion layer can improve the consistency of devices in the process and improve the yield of process. By introducing the insertion layer on the top electrode, lower structures can be protected, not only preventing these structures from being damaged during processing, but also protecting these structures from corrosion by such as water vapor in the environment during use of the device, thereby improving the reliability of the device. Moreover, the positions of outer edges of the at least one mass load can be defined, thereby ensuring that the at least one mass load can bring positive influence to the improvement of performance, and that the improvement of the performance of the piezoelectric resonator has good effect.

The operation S3 includes patterning the top electrode layer to obtain a top electrode, which is applicable to a plurality of types of piezoelectric resonators, and has a wide range of applications.

After the operation S5, the method further includes:
at S6, a passivation layer is formed by deposition on a side of the mass load layer away from the insertion layer. The passivation layer is used to protect the top electrode layer and/or bottom electrode layer, thereby increasing the service life of the piezoelectric resonator.

The method further includes:
at S7, the passivation layer, the mass load layer, the insertion layer, and the top electrode layer are patterned, to make an edge of the passivation layer, an edge of the mass load layer, an edge of the insertion layer, and an edge of the top electrode layer align with each other.

The method further includes: forming a cavity by etching on a surface of the substrate, depositing a sacrificial material to fill the cavity, and polishing the sacrificial material by chemical mechanical polishing to make the sacrificial material flush with the surface of the substrate. The sacrificial layer structure is configured to be released at an end of the process to empty the cavity, and the cavity is configured to reflect acoustic waves to form the acoustic wave reflection structure.

The method further includes: forming a sacrificial layer by deposition on the substrate, patterning the sacrificial layer, and forming a support layer by deposition on a side of the sacrificial layer away from the substrate. The sacrificial layer is configured to be released at an end of the process to form a cavity, and the cavity is configured to reflect acoustic waves to form the acoustic wave reflection structure.

The method further includes: forming a support layer by deposition on the substrate, forming a cavity on a surface of the support layer away from the substrate by etching the support layer, depositing a sacrificial material to fill the cavity, and leveling the sacrificial material by chemical mechanical polishing to make the sacrificial material flush with the surface of the substrate. The sacrificial layer is configured to be released at an end of the process to empty the cavity, and the cavity is configured to reflect acoustic waves to form the acoustic wave reflection structure.

The method further includes: forming a plurality of layers of materials having different acoustic impedances on the substrate by deposition to form a Bragg mirror configured to reflect acoustic waves and to form the acoustic wave reflection structure.

The method further includes: etching the passivation layer on a surface of the passivation layer away from the mass load layer to form a top electrode contacting hole communicating with the top electrode layer.

The method further includes: etching the passivation layer and/or the piezoelectric layer on a surface of the passivation layer away from the mass load layer to form a bottom electrode contacting hole communicating with the bottom electrode.

The method further includes: forming an interconnecting metal layer by deposition on a side of the passivation layer away from the mass load layer. The interconnecting metal layer fills the top electrode contacting hole and/or the bottom electrode contacting hole.

Compared with the related technologies, in the piezoelectric resonator provided by the present disclosure, the piezoelectric layer is formed on a side of the bottom electrode; the top electrode is formed on a side of the piezoelectric layer away from the bottom electrode; the acoustic wave reflection structure is formed on a side of the bottom electrode away from the piezoelectric layer, and the top electrode, the piezoelectric layer, the bottom electrode, and the acoustic wave reflection structure overlap to form a resonant region; the at least one insertion layer is formed on a side of the top electrode away from the piezoelectric layer and/or on the side of the bottom electrode away from the piezoelectric layer, and the at least one insertion layer at least partially covers the resonant region; each mass load of the at least one mass load is formed on a side of a respective insertion layer of the at least one insertion layer away from the piezoelectric layer, and the at least one mass load is at least partially formed in the resonant region. By using the at least one insertion layer as etching-stop layer(s), during patterning of the at least one mass load, it can be ensured that the etching of the at least one mass load stops at the at least one insertion layer and the top electrode will not be etched, thereby improving the consistency of devices in the process and improving the yield of process. By introducing the at least one insertion layer on the top electrode, lower structures can be protected, not only preventing these structures from being damaged during processing, but also protecting these structures from corrosion by such as water vapor in the environment during use of the device, thereby improving the reliability of the device. The present disclosure also defines the positions of outer edges of the at least one mass load, thereby ensuring that the at least one mass load can substantially improve the performance of the resonator and increase the FOM.

The above mentioned are only the embodiments of the present disclosure. It should be pointed out that for those skilled in the art, improvements can be made without departing from the inventive concept of the present disclosure, but these improvements are all within the scope of protection of the present disclosure.

What is claimed is:

1. A piezoelectric resonator, comprising:
a bottom electrode;
a piezoelectric layer, formed on a side of the bottom electrode;
a top electrode, formed on a side of the piezoelectric layer away from the bottom electrode;
an acoustic wave reflection structure, formed on a side of the bottom electrode away from the piezoelectric layer, wherein the top electrode, the piezoelectric layer, the bottom electrode, and the acoustic wave reflection structure overlap to form a resonant region;
at least one insertion layer, formed on a side of the top electrode away from the piezoelectric layer and/or on the side of the bottom electrode away from the piezoelectric layer, wherein the at least one insertion layer at least partially covers the resonant region; and
at least one mass load, wherein each mass load of the at least one mass load is formed on a side of a respective insertion layer of the at least one insertion layer away from the piezoelectric layer, wherein the at least one mass load is at least partially formed in the resonant region.

2. The piezoelectric resonator according to claim 1, further including a substrate formed on the side of the bottom electrode away from the piezoelectric layer.

3. The piezoelectric resonator according to claim 2, wherein the acoustic wave reflection structure is formed by a recess on a surface of the substrate facing towards the bottom electrode or by a cavity formed between the substrate and the bottom electrode, wherein the cavity is at least partially formed in the resonant region.

4. The piezoelectric resonator according to claim 1, wherein the acoustic wave reflection structure is a Bragg mirror formed on a side of the bottom electrode away from the top electrode and formed at least partially in the resonant region.

5. The piezoelectric resonator according to claim 1, wherein the at least one mass load forms a structure of closed annulus.

6. The piezoelectric resonator according to claim 1, wherein the at least one mass load forms a structure of unclosed annulus obtained by removing at least one corner or side of a structure of closed annulus.

7. The piezoelectric resonator according to claim 1, wherein the at least one mass load forms a structure of unclosed annulus obtained by forming at least one notch on a structure of closed annulus, wherein the at least one notch has side walls opposite to each other, and the at least one notch is perpendicular to outer edges of the structure of unclosed annulus along an extension direction of the side walls.

8. The piezoelectric resonator according to claim 7, wherein the structure of unclosed annulus has two or more than two notches, and the two notches or at least two notches of the more than two notches are formed on a same longitudinal section of the piezoelectric resonator.

9. The piezoelectric resonator according to claim 1, wherein the at least one mass load is arranged to form a shape same as a shape of the resonant region, and each outer edge of outer edges of the shape formed by the at least one mass load is parallel to a respective outer edge of outer edges of the resonant region.

10. The piezoelectric resonator according to claim 1, wherein at least one outer edge of outer edges of a shape formed by the at least one mass load is not parallel to at least one respective outer edge of outer edges of the resonant region.

11. The piezoelectric resonator according to claim 1, wherein insertion layers and mass loads are formed on either sides of the piezoelectric layer;
wherein the insertion layers include a first insertion layer and a second insertion layer, the first insertion layer is formed on the side of the top electrode away from the piezoelectric layer, and the second insertion layer is formed on the side of the bottom electrode away from the piezoelectric layer; and
wherein the mass loads include a first mass load and a second mass load, the first mass load is formed on a side of the first insertion layer away from the top electrode, and the second mass load is formed on a side of the second insertion layer away from the bottom electrode.

12. The piezoelectric resonator according to claim 1, further including at least one passivation layer, wherein each passivation layer of the at least one passivation layer is formed on the side of a respective insertion layer of the at least one insertion layer away from the piezoelectric layer, the at least one passivation layer at least partially covers the resonant region.

13. A method for manufacturing a piezoelectric resonator, comprising:
forming a bottom electrode layer on a substrate by deposition, and patterning the bottom electrode layer to obtain a bottom electrode, wherein the substrate has an acoustic wave reflection structure or a sacrificial layer structure formed on a surface of the substrate;
forming a piezoelectric layer by deposition on a side of the bottom electrode layer away from the substrate;
forming a top electrode layer by deposition on a side of the piezoelectric layer away from the bottom electrode layer;
forming an insertion layer by deposition on a side of the top electrode layer away from the piezoelectric layer; and
forming a mass load layer by deposition on a side of the insertion layer away from the top electrode layer, and patterning the mass load layer to obtain at least one mass load.

14. The method according to claim 13, wherein forming the top electrode layer by deposition on the side of the piezoelectric layer away from the bottom electrode layer, includes:
patterning the top electrode layer to obtain a top electrode.

15. The method according to claim 13, wherein after patterning the mass load layer, the method further includes:
forming a passivation layer by deposition on a side of the mass load layer away from the insertion layer.

16. The method according to claim 15, further including:
pattering the passivation layer, the mass load layer, the insertion layer, and the top electrode layer, to make an edge of the passivation layer, an edge of the mass load layer, an edge of the insertion layer, and an edge of the top electrode layer align with each other.

17. The method according to claim 13, further including:
forming a cavity by etching on a surface of the substrate;
depositing a sacrificial material to fill the cavity; and
polishing the sacrificial material by chemical mechanical polishing to make the sacrificial material flush with the surface of the substrate;
wherein the sacrificial layer structure is configured to be released at an end of the method to empty the cavity, and the cavity is configured to reflect acoustic waves to form the acoustic wave reflection structure.

18. The method according to claim 13, further including:
forming a sacrificial layer by deposition on the substrate;
patterning the sacrificial layer; and
forming a support layer by deposition on a side of the sacrificial layer away from the substrate;
wherein the sacrificial layer is configured to be released at an end of the method to form a cavity, and the cavity is configured to reflect acoustic waves to form the acoustic wave reflection structure.

19. The method according to claim 13, further including:
forming a support layer by deposition on the substrate;
forming a cavity on a surface of the support layer away from the substrate by etching the support layer;
depositing a sacrificial material to fill the cavity; and
leveling the sacrificial material by chemical mechanical polishing to make the sacrificial material flush with the surface of the substrate;
wherein the sacrificial layer is configured to be released at an end of the method to empty the cavity, and the cavity is configured to reflect acoustic waves to form the acoustic wave reflection structure.

20. The method according to claim 13, further including:
forming a plurality of layers of materials having different acoustic impedances on the substrate by deposition to form a Bragg mirror configured to reflect acoustic waves and to form the acoustic wave reflection structure.
